(19) United States
(12) Patent Application Publication
(10) Pub. No.: US 2016/0069973 A1
(43) Pub. Date: Mar. 10, 2016

(54) COMBINED MAGNETIC RESONANCE-EMISSION TOMOGRAPHY DEVICE, AND METHOD FOR IMAGING AN EXAMINATION OBJECT THEREWITH

(71) Applicant: SIEMENS AKTIENGESELLSCHAFT, Muenchen (DE)

(72) Inventors: Matthias Fenchel, Erlangen (DE); Wilhelm Horger, Schwaig (DE); Berthold Kiefer, Erlangen (DE); Marcel Dominik Nickel, Herzogenaurach (DE)

(73) Assignee: SIEMENS AKTIENGESELLSCHAFT, Muenchen (DE)

(21) Appl. No.: 14/845,674

(22) Filed: Sep. 4, 2015

(30) Foreign Application Priority Data
Sep. 4, 2014 (DE) 102014217730.8

(51) Int. Cl. G01R 33/48; G01R 33/561; G01T 1/16

(52) U.S. Cl. CPC G01R 33/481; G01T 1/1603; G01R 33/4828; G01R 33/5611

(57) ABSTRACT

In a combined magnetic resonance (MR)-emission tomography apparatus, MR scan data and emission tomography scan data are acquired from a subject in the apparatus. MR image data are generated from the MR scan data, and an attenuation map is generated from the same MR scan data that were used to generate the MR image data. Emission tomography image data are generated by applying a correction algorithm, which uses the attenuation map, to the emission tomography scan data. The MR image data and the emission tomography emission data are then presented.

### BACKGROUND OF THE INVENTION

1. Field of the Invention

The invention concerns a method for imaging an examination object by operation of a combined magnetic resonance-emission tomography apparatus, as well as a combined magnetic resonance-emission tomography apparatus and a method for selecting at least one sequence parameter of a magnetic resonance sequence for such an apparatus.

2. Description of the Prior Art

In a magnetic resonance apparatus, also known as a magnetic resonance tomography system, typically the body of a person to be examined, particularly that of a patient, is exposed to a relatively strong magnetic field of for example, 1.5 or 3 or 7 Tesla, with the use of a basic field magnet. In addition, gradient switching sequences are activated by a gradient coil arrangement. With a radio-frequency antenna unit, using suitable antenna devices, radio-frequency pulses, particularly excitation pulses, are emitted, which cause the nuclear spins of particular atoms excited into resonance by these radio-frequency pulses to be tilted through a defined flip angle relative to the magnetic field lines of the basic magnetic field. During relaxation of the nuclear spins, radio-frequency signals known as “magnetic resonance signals” are emitted and are received by suitable radio-frequency antennae and then further processed. From the raw data acquired in this manner, the desired image data can be reconstructed.

For a particular scan, a specific magnetic resonance sequence, also known as a “pulse sequence,” is employed, which includes a series of radio-frequency (RF) pulses, in particular excitation pulses and refocusing pulses, as well as gradient switching sequences emitted in coordination with the RF pulses on various gradient axes along different spatial directions. Temporally adapted thereto, readout windows are set that specify the time frames within which the emitted magnetic resonance signals are acquired.

Positron emission tomography (PET) and single photon emission computed tomography (SPECT) are imaging modalities in nuclear medicine, wherein typically sectional images of an examination object are generated. Such images represent the distribution of a weakly radioactively labeled substance introduced in the body of the examination object; that is measured and made visible with a radiation detector, particularly a specially designed PET detector unit or SPECT detector unit. In this way, biochemical and physiological processes can be imaged in an organ of the examination object. For this purpose, a radionuclide or a substance labeled with a radionuclide is injected into the examination object before an examination.

For a PET examination, the radionuclide emits positrons. When a positron interacts with an electron in the body of the examination object, two photons are emitted in opposite directions and the coincidences are registered with the PET detector unit of the PET device. From these registered random events, the spatial distribution of the radionuclide in the interior of the body can be determined and sectional images of the body interior of the living being can be generated.

In order to evaluate the results of an emission tomography scan, an attenuation map is needed that represents a spatially-resolved distribution of the attenuation values of the tissue of the current examination object. The attenuation values are typically stored in the form of linear attenuation coefficients with units of 1/cm. With regard to attenuation correction, the tissue of the examination object which lies between the site of origin of the photons and the emission tomography detector is particularly relevant. With the use of the attenuation map, the emission tomography data are corrected during the evaluation. In the case of PET imaging, the attenuation map represents attenuation values relating to photons with an energy of 511 keV.

Medical examinations are frequently carried out by combined medical imaging devices having more than one imaging modality, typically two imaging modalities. In these medical examinations, diagnostic scan data from an examination object are acquired by the multiple, particularly two, imaging modalities, usually simultaneously. Assessment of the diagnostic image data reconstructed from the diagnostic scan data is thereby facilitated for an expert, since the expert has the image data of both imaging modalities available. For example, combined magnetic resonance-emission tomography devices are known. These include, for example, a combined magnetic resonance-positron emission tomography device (magnetic resonance-PET device) and a combined magnetic resonance-single photon emission computed tomography device (magnetic resonance-SPECT device).

In simultaneous magnetic resonance-emission tomography examinations, the entire examination duration is typically determined by the duration for the recording of magnetic resonance scan data. One reason therefor is that typically a large number of different diagnostic magnetic resonance sequences are used to acquire the magnetic resonance scan data. Furthermore, in simultaneous magnetic resonance-emission tomography examinations, an examination region of the examination object in an axial direction along a longitudinal axis of the examination object can be restricted by the examination field of the emission tomography detector that is used. This can mean that the acquisition of the magnetic resonance scan data and emission tomography scan data must take place for a number of bed positions in order to cover a desired examination region along the axial direction. This means, in particular, that a patient support, on which the examination object is positioned during the acquisition of the magnetic resonance scan data and the emission tomography scan data, must be moved during the magnetic resonance-emission tomography examination. This may require that the magnetic resonance data acquisition unit (scanner) must be adjusted anew after each displacement of the patient support.

The aforementioned attenuation map for attenuation correction of the emission tomography scan data is typically generated in a combined magnetic resonance-emission tomography examination based on a separate magnetic resonance data set, which is acquired from the examination object by the magnetic resonance scanner. This magnetic resonance data set must be recorded in addition to the actual diagnostic magnetic resonance scan data.

### SUMMARY OF THE INVENTION

An object of the invention is to provide an advantageously matched generation of diagnostic magnetic resonance image data and an attenuation map for attenuation correction of emission tomography scan data.

This object is achieved in accordance with the invention by a method for imaging an examination object by operation of a combined magnetic resonance-emission tomography device that includes the following steps:

Magnetic resonance scan data of the examination object are acquired by operation of a magnetic resonance scanner of the magnetic resonance-emission tomography apparatus.

Emission tomography scan data of the examination object are acquired by operation of an emission tomography scanner of the magnetic resonance-emission tomography apparatus.

Magnetic resonance image data are generated from the magnetic resonance scan data.

An attenuation map is generated using the acquired magnetic resonance scan data that are used to generate the magnetic resonance image data to be displayed.

Emission tomography image data are generated by executing an attenuation correction of the emission tomography scan data, with the attenuation correction being executed using the generated attenuation map.

The magnetic resonance image data and the emission tomography image data are shown on a display monitor.

The examination object can be a patient, a training person or a phantom. The acquisition of the magnetic resonance scan data and the emission tomography scan data takes place particularly during a magnetic resonance-emission tomography examination of a single examination object. This means that the magnetic resonance scan data and emission tomography scan data are acquired for diagnostic purposes after the positioning of the examination object within the magnetic resonance-emission tomography device for recording the magnetic resonance scan data and emission tomography scan data. It should also be noted that the sequence of method steps described can be varied. Thus, for example, the generation of the magnetic resonance image data can also take place before the acquisition of the emission tomography scan data or after the generation of the attenuation map or after the generation of the emission tomography image data.

The magnetic resonance scan data are acquired by execution of a diagnostic magnetic resonance sequence. This means that the magnetic resonance image data generated from the magnetic resonance scan data are provided for a diagnostic assessment by an expert, for example, a radiologist. The generation of the magnetic resonance image data from the magnetic resonance scan data can include a reconstruction of the magnetic resonance image data from the magnetic resonance scan data. For this purpose, the magnetic resonance scan data are entered into a memory organized as k-space. The magnetic resonance image data can be stored in the image domain. The magnetic resonance image data are presented as an output on the display monitor, in particular for diagnostic assessment by the expert. Thus, the magnetic resonance image data can be made available to the expert. The magnetic resonance image data can be shown together with the emission tomography image data on the display monitor. It is particularly advantageous for the magnetic resonance image data to be shown overlaid and/or merged with the emission tomography image data.

According to the inventive procedure, the magnetic resonance scan data are not only used to generate magnetic resonance image data that are ultimately shown on the display monitor, but also the magnetic resonance scan data are used to generate the attenuation map. The generation of the attenuation map using the magnetic resonance scan data can take place, by determining, from of the magnetic resonance scan data, information as to a spatially-resolved distribution of attenuation values of a tissue of the examination object. According to the inventive procedure, the magnetic resonance scan data are thus used both to generate the attenuation map and to generate the magnetic resonance image data that are shown on the display monitor. Advantageously, the same magnetic resonance scan data are used both to generate the attenuation map and to generate the magnetic resonance image data. This means that, from a single set of information entered in k-space, both the attenuation map and the magnetic resonance image data are generated. Thus, the acquired magnetic resonance scan data particularly play an important role in the generation of the emission tomography image data, since they are used indirectly in the attenuation correction of the emission tomography scan data.

According to the inventive procedure, the magnetic resonance scan data therefore perform a particularly advantageous double function. They are advantageously suitable firstly for the reconstruction of diagnostic magnetic resonance image data which are displayed for a competent person. Secondly, the magnetic resonance scan data are suitable for generating an attenuation map. This results in the advantage that acquisition of a separate magnetic resonance data set used for generating the attenuation map can be omitted. Thus a scan time for acquiring the separate magnetic resonance data set can be omitted. Time-consuming adjustments of a magnetic resonance scanner for acquiring the separate magnetic resonance data set can also be omitted. Thus, particularly advantageously, the total examination time of a combined magnetic resonance-emission tomography examination can be reduced. This is in comparison to the typical total scan time of the magnetic resonance scanner that because of the multiple contrast levels that must be recorded, is conventionally a fixed time duration.

Furthermore, through the simultaneous use of the magnetic resonance scan data for the generation of the magnetic resonance image data and the attenuation map, a particularly advantageous matching of the magnetic resonance image data to the attenuation map generated and thus to the emission tomography image data generated by the attenuation map are achieved. It can be ensured that the generation of the magnetic resonance image data and the emission tomography image data are based on the same magnetic resonance scan data. Thus, for example, a similar breathing movement of the examination object is present in the generated magnetic resonance image data and the generated attenuation map. Thus, for example, registration and/or merging of the magnetic resonance image data with the emission tomography image data can be improved.

It should be noted that the generation of the magnetic resonance image data from the magnetic resonance scan data can be performed by means of a method familiar to those skilled in the art, so that an explanation is not needed in detail herein. The attenuation correction of the emission tomography scan data using the generated attenuation map for generation of the emission tomography image data can also be performed by a method familiar to those skilled in the art, so a detailed explanation is not needed herein.

In an embodiment, the acquisition of the magnetic resonance scan data and of the emission tomography scan data takes place at least partially simultaneously. The acquisition of the magnetic resonance scan data and the emission tomography scan data advantageously takes place largely, and highly advantageously, entirely simultaneously. This means that the emission tomography scan data are acquired simultaneously with the magnetic resonance scan data from the examination object. In this way, an examination duration of the combined magnetic resonance-emission tomography examination can be reduced. It can further be ensured that the emission tomography scan data are particularly advantageously matched to the magnetic resonance scan data since, for example, the examination object has the same position during acquisition of the emission tomography scan data and of the magnetic resonance scan data.

In another embodiment, the magnetic resonance scan data are configured such that the magnetic resonance image data generated from the magnetic resonance scan data have an image quality sufficient for a diagnostic assessment. For this purpose, a magnetic resonance sequence can be used for acquiring the magnetic resonance scan data which has sequence parameters such that magnetic resonance image data generated from the magnetic resonance scan data have the sufficient image quality. The magnetic resonance sequence can be embodied in a magnetic resonance protocol. The image quality sufficient for a diagnostic assessment can be pre-set by a user. The image quality can be quantified using at least one image quality parameter. Then at least one minimum value for the at least one image quality parameter can be set. In this way, it can be stipulated that the magnetic resonance image data then have a sufficient image quality for a diagnostic assessment if the at least one image quality parameter is higher than the at least one minimum value. The at least one image quality parameter can be selected, for example, from the following list: a signal-to-noise ratio (SNR) of the magnetic resonance image data, a contrast-to-noise ratio (CNR) of the magnetic resonance image data, a resolution of the magnetic resonance image data, an artifact freedom of the magnetic resonance image data. Any desired combination of multiple image quality parameters from this list can also be used for quantifying the image quality of the magnetic resonance image data. Naturally, other image quality parameters that those skilled in the art would deem useful are also conceivable. The at least one image quality parameter can be averaged over the magnetic resonance image data. Alternatively or additionally, for acquiring the magnetic resonance scan data, a magnetic resonance sequence can be used that is configured so that magnetic resonance image data have the sufficient image quality. Such magnetic resonance sequences can be present, specially marked, in a database of the magnetic resonance-emission tomography device and called from the database for acquisition of the magnetic resonance scan data. The identification of suitable magnetic resonance sequences can take place in a prior identification step in which magnetic resonance sequences for acquiring the diagnostic magnetic resonance scan data can be marked as valid. As a whole, by one of the procedures described, it can be ensured that the magnetic resonance image data generated from the magnetic resonance scan data are suitable for an assessment by an expert, for example, a radiologist. In this way, the magnetic resonance scan data can particularly advantageously fulfill their double function that, aside from being suitable for creating an attenuation map, the data are suitable for diagnostic assessment.

In a further embodiment, the magnetic resonance scan data are configured so that a resolution of the magnetic resonance image data generated from the magnetic resonance scan data is higher at least in one spatial direction than a resolution of the emission tomography image data. Advantageously, the resolution of the magnetic resonance image data in the at least one spatial direction is at least twenty percent higher than the resolution of the emission tomography image data. An in-plane resolution of the magnetic resonance image data is preferably higher than that of the emission tomography image data. This means that the resolution of the magnetic resonance image data is higher in two spatial directions than the resolution of the emission tomography image data, wherein the two spatial directions are arranged perpendicular to a slice direction of the magnetic resonance image data. The resolution of the magnetic resonance image data in the slice direction can then be selected to be coarser in order to improve a signal-to-noise ratio. It is also conceivable that the resolution of the magnetic resonance image data in all spatial directions is higher than the resolution of the emission tomography image data. The fact that the resolution of the magnetic resonance image data is higher than the resolution of the emission tomography image data means that the magnetic resonance image data have a finer resolution than the emission tomography image data. For generation of the attenuation map, a resolution of the magnetic resonance image data matched to the resolution of the emission tomography image data would be sufficient. The higher resolution magnetic resonance image data are however particularly suitable for a diagnostic assessment by an expert. Furthermore, with a higher resolution magnetic resonance image data, a more finely resolved attenuation map, which can have fewer partial volume artifacts, can be generated. Magnetic resonance scan data configured in this way thus fulfill their double function particularly well.

In another embodiment, the acquisition of the magnetic resonance scan data takes place by operation of a magnetic resonance sequence which uses a Dixon technique with an acceleration technique. The Dixon technique is a method that is known to those skilled in the art for separating fat signals and water signals in magnetic resonance scan data acquired with the Dixon technique. With the Dixon technique, typically two echoes are recorded following a single excitation, specifically an image wherein the phase difference between the water and fat signals is zero and a further image in which the phase difference between the water and fat signals is 180°. Thus one image represents the addition of water and fat signals and the other image represents a subtraction of water and fat signals. From this, the fat/water ratio within a voxel can be determined. The Dixon technique is known to those skilled in the art so that a detailed description is omitted here. Magnetic resonance scan data acquired by the Dixon technique offer a particularly advantageous basis for generating the attenuation map. Specifically, in the generation of the attenuation map, an advantageous differentiation takes place between water-containing tissue and fatty tissue of the examination object. Thus, different attenuation values can advantageously be assigned to the water-containing tissue and the fatty tissue of the examination object. The accuracy of the reconstruction of the emission tomography scan data by use of the attenuation map can thus be improved. At the same time, from magnetic resonance scan data acquired with the Dixon technique, advantageous diagnostic magnetic resonance image data can be reconstructed. In particular, from magnetic resonance scan data acquired by the Dixon technique, magnetic resonance image data that have fat suppression can be reconstructed. At the same time, from magnetic resonance scan data acquired by the Dixon technique, magnetic resonance image data that have a T1-weighting can be reconstructed. Such T1-weighted magnetic resonance image data with fat suppression can be particularly suitable for a diagnostic assessment by a competent person, particularly for oncological investigations. The acceleration technique can be, for example, a GRAPPA method or a SENSE recording method. The acceleration technique can involve undersampling of k-space to be filled. The acceleration technique can also be a parallel imaging technique. Parallel imaging techniques are based on parallel acquisition of magnetic resonance signals by different receiving units of radio-frequency coils. Acceleration techniques are known to those skilled in the art so that a detailed description is not necessary herein. The inventive use of such an acceleration technique can lead to a shortening of a scan time of the magnetic resonance sequence for acquiring the magnetic resonance scan data. The use of the acceleration technique can ensure that the magnetic resonance scan data can be recorded completely during a breath-holding process of the examination object. This can lead to an increase in a quality of the magnetic resonance scan data, so the magnetic resonance scan data are, for example, suitable for generating the attenuation map. As a whole, the combined use of the Dixon technique with the acceleration technique offers the advantage that the magnetic resonance scan data thus acquired can, firstly, be used to generate diagnostic magnetic resonance image data and can, secondly, be used for generating the attenuation map for reconstruction of the emission tomography image data.

In an embodiment, the acceleration technique uses a CAIPIRINHA (Controlled Aliasing In Parallel Imaging Results In Higher Acceleration) method. If a CAIPIRINHA method is used for acquiring the magnetic resonance scan data, the generation of the magnetic resonance image data can be a reconstruction of the magnetic resonance image data from the magnetic resonance scan data by a CAIPIRINHA reconstruction method. The CAIPIRINHA method is known from U.S. Pat. No. 7,002,344 B2. Advantageous embodiments of the CAIPIRINHA method are known for example from US 20130271128 A1 and from U.S. Pat. No. 8,717,020 B2. The CAIPIRINHA method can be used as a particularly advantageous acceleration technique in combination with the Dixon technique. Specifically, the CAIPIRINHA method enables, firstly, a particularly large reduction in a scan time of the magnetic resonance sequence since particularly large acceleration factors can be used. Thus the scan time of the magnetic resonance sequence for acquiring the magnetic resonance scan data can be further reduced. The reduction of the scan time can thus be used, for example, for increasing the scan resolution of the magnetic resonance scan data. Thus, by the use of the CAIPIRINHA recording method, a resolution of the magnetic resonance image data reconstructed from the magnetic resonance scan data can be increased. A maximum scan duration for acquiring the magnetic resonance scan data can be pre-set, for example, dependent on the maximum breath-holding duration of the examination object. In this way, a required diagnostic image quality of the magnetic resonance image data can be particularly easily achieved. A resolution of the magnetic resonance image data reconstructed from the magnetic resonance scan data is possible that is at least double the size of a resolution of the emission tomography image data is possible. Thus higher resolution magnetic resonance image data can be reconstructed and/or a higher resolution attenuation map can be generated from the magnetic resonance scan data. The use of the CAIPIRINHA method in combination with the Dixon technique therefore enables the magnetic resonance scan data thus acquired to be particularly suitable for generating the diagnostic magnetic resonance image data and the attenuation map. A high resolution attenuation map can enable a precise differentiation between different tissue types and the prevention of partial volume artifacts. The use of an attenuation map based on magnetic resonance scan data thus acquired for attenuation correction of the emission tomography scan data can lead to an increase in an accuracy of the reconstructed emission tomography image data. As a whole, magnetic resonance scan data acquired by means of the inventive combination of the Dixon technique with the CAIPIRINHA method can particularly advantageously fulfill its double function for generating the magnetic resonance image data and the attenuation map.

In another embodiment, the attenuation map is generated using the magnetic resonance image data that are generated from the magnetic resonance scan data. In this way, the attenuation map is preferably generated from the magnetic resonance image data which are provided for output on the display monitor. The magnetic resonance image data are thus, firstly, output on the display monitor and, secondly, used for generating the attenuation map. This procedure is based on the consideration that the attenuation map is typically present in the form of a three-dimensional data set. Thus the reconstructed magnetic resonance image data which are advantageously present in the form of a three-dimensional data set can particularly advantageously be used to generate the attenuation map. The magnetic resonance image data are further processed for generating the attenuation map. The magnetic resonance image data therefore perform a particularly advantageous double function.

In another embodiment, before the generation of the attenuation map, a transformation of the magnetic resonance image data takes place, and transformed magnetic resonance image data are created, wherein the generation of the attenuation map takes place using the transformed magnetic resonance image data. The non-transformed magnetic resonance image data are shown on the display monitor and the transformed magnetic resonance image data are used for generating the attenuation map. The transformation of the magnetic resonance image data is initially used, in particular, only for the generation of the attenuation map. In particular, therefore, the magnetic resonance image data which are output on the display monitor are not used directly for generating the attenuation map, but are initially transformed before the generation of the attenuation map. The transformation of the magnetic resonance image data typically comprises a change of a geometry of the magnetic resonance image data. The transformation of the magnetic resonance image data can be, for example, a change of a resolution of the magnetic resonance image data and/or a scaling of the magnetic resonance image data and/or a translation of the magnetic resonance image data and/or a rotation of the magnetic resonance image data. Particularly advantageous is a change of a slice orientation of the magnetic resonance image data described in the following paragraph. Naturally, other possibilities that those skilled in the art would deem useful for transforming the magnetic resonance image data are also conceivable. Advantageously, a geometry of the transformed magnetic resonance image data is adapted to a geometry of the emission tomography scan data and/or emission tomography image data. Through the adaptation of the geometry of the magnetic resonance image data, by the transformed magnetic resonance image data, an attenuation map can be created the geometry of which is matched to the emission tomography scan data and/or the emission tomography image data. Thus the attenuation map generated by means of the transformed magnetic resonance image data can be particularly easily used for attenuation correction of the emission tomography scan data.

In another embodiment, the transformation of the magnetic resonance image data is a change of the slice orientation of the magnetic resonance image data. The transformation of the magnetic resonance image data can therefore be a multiplanar reformatting of the magnetic resonance image data. In particular, an orthogonal change in the slice orientation of the magnetic resonance image data takes place. This can mean, for example, that an axial slice orientation of the transformed magnetic resonance image data is changed into a transversal or sagittal slice orientation of the transformed magnetic resonance image data. Through the change of the slice orientation, a slice orientation of the magnetic resonance image data can be changed particularly advantageously, for example, to a slice orientation of the transformed magnetic resonance image data necessary for generating the attenuation map.

In another embodiment, the acquisition of the magnetic resonance scan data takes place by execution of a magnetic resonance sequence which has at least one sequence parameter and the generation of the attenuation map comprises post-processing of the magnetic resonance scan data using at least one post-processing parameter, wherein the at least one post-processing parameter is set using the at least one sequence parameter. The at least one sequence parameter can be, for example, a geometry of a sampling volume of the magnetic resonance scan data, a resolution, an echo time, a repetition time, a number of averagings, etc. Naturally, other sequence parameters deemed useful by those skilled in the art are also conceivable. Based on the at least one sequence parameter, a sequence of control commands for the magnetic resonance sequence for acquiring the magnetic resonance scan data is set, particularly automatically. Such control commands are, for example, radio-frequency pulses, gradient switching sequences or readout time windows. Post-processing parameters which are generated using the at least one sequence parameter can comprise, for example, segmentation parameters. Segmentation parameters are, for example, a selection of a filter for the segmentation, a signal normalization or an adaptation of a threshold value for the segmentation. Naturally, further sequence parameters deemed useful by a skilled person and which are generated using the at least one sequence parameter are also conceivable. The segmentation parameters which are generated using the at least one sequence parameter can be used for a segmentation of the magnetic resonance image data generated from the magnetic resonance scan data into a number of material classes for generating the attenuation map. Post-processing parameters that are generated using the at least one sequence parameter can further include registration parameters. This is particularly useful if for the generation of the attenuation map, a registration takes place using the magnetic resonance scan data. An exemplary registration parameter is a type of registration used or a required minimum registration accuracy. Aside from segmentation parameters and registration parameters, further post-processing parameters are naturally also conceivable. As a whole, by means of the procedure described, the post-processing of the magnetic resonance image data can particularly advantageously be matched to properties of the magnetic resonance image data. The properties of the magnetic resonance image data can herein be determined particularly easily from the at least one sequence parameter that is used for acquiring the magnetic resonance scan data from which the magnetic resonance image data are generated.

In another embodiment, the post-processing of the magnetic resonance scan data includes a segmentation of the magnetic resonance image data generated from the magnetic resonance scan data into a number of material classes, with different values of attenuation coefficients being assigned to the number of material classes. The acquisition of the magnetic resonance scan data advantageously takes place by execution of a magnetic resonance sequence that has sequence parameters, and the segmentation of the magnetic resonance image data takes place using segmentation parameters, with the segmentation parameters being generated using the sequence parameters. To this end, the magnetic resonance scan data are configured so that the magnetic resonance image data generated from the magnetic resonance scan data are segmentable into a number of material classes. More advantageously, the magnetic resonance scan data are configured so that the magnetic resonance image data generated from the magnetic resonance scan data have a minimum contrast difference between the number of material classes. The minimum contrast difference can be pre-set. Advantageously, the minimum contrast difference is configured so that, by common segmentation methods, a segmentation of the magnetic resonance image data into the number of material classes is possible. The number of material classes can comprise, for example, fatty tissue, water-bearing tissue, air, bone tissue, lung tissue, etc. Naturally, any desired combination of the material classes mentioned is possible. Other material classes deemed useful by those skilled in the art are also conceivable. A segmentation of the magnetic resonance image data into three material classes, specifically air, fatty tissue and water-bearing tissue has proved to be useful. Particularly advantageous is a segmentation of the magnetic resonance image data into four material classes, specifically air, fatty tissue, water-bearing tissue and bone tissue. In addition, a segmentation into a lung tissue material class is advantageous. The attenuation coefficients associated with the number of material classes can be stored in a database. Following the segmentation of the magnetic resonance image data into the number of material classes, the magnetic resonance image data can be transferred particularly easily into an attenuation map in that the respective attenuation coefficients which are associated with the number of material classes are set for the segmented regions in the magnetic resonance image data. In this way, an advantageous generation of the attenuation map from the magnetic resonance image data is possible.

Furthermore, the invention encompasses a combined magnetic resonance-emission tomography apparatus having a magnetic resonance scanner, an emission tomography scanner, a display monitor and a computer that has a magnetic resonance image data generating storage or module, an attenuation map generating stage or module and an emission tomography image data generating stage or module, wherein the combined magnetic resonance-emission tomography apparatus is configured to implement the method according to the invention.

The magnetic resonance scanner is configured to acquire magnetic resonance scan data of the examination object. The emission tomography scanner is configured to acquire emission tomography scan data of the examination object. The magnetic resonance image data generating stage is configured to generate magnetic resonance image data from the magnetic resonance scan data. The attenuation map generating stage is configured for generating an attenuation map using the acquired magnetic resonance scan data that are used to generate the magnetic resonance image data to be displayed. The emission tomography image data generating stage is configured to generate emission tomography image data by means of an attenuation correction of the emission tomography scan data, wherein the attenuation correction is executed using the generated attenuation map. The display monitor is configured to show the magnetic resonance image data and the emission tomography image data.

According to an embodiment of the combined magnetic resonance-emission tomography apparatus, the magnetic resonance scanner and the emission tomography scanner are configured so that the acquisition of the magnetic resonance scan data and the emission tomography scan data take place at least partially simultaneously.

In another embodiment of the combined magnetic resonance-emission tomography apparatus, the magnetic resonance scanner is configured so that the magnetic resonance scan data are configured so that the magnetic resonance image data generated from the magnetic resonance scan data have an image quality sufficient for a diagnostic assessment.

In another embodiment of the combined magnetic resonance-emission tomography apparatus, the magnetic resonance scanner is configured so that a resolution of the magnetic resonance image data generated from the magnetic resonance scan data is at least twice as high as a resolution of the emission tomography image data.

In another embodiment of the combined magnetic resonance-emission tomography apparatus, the magnetic resonance scan data are configured so that a resolution of the magnetic resonance image data generated from the magnetic resonance scan data is higher at least in one spatial direction than a resolution of the emission tomography image data.

In a further embodiment of the combined magnetic resonance-emission tomography apparatus, the magnetic resonance scanner is configured so that the acceleration technique uses a CAIPIRINHA recording method.

In another embodiment of the combined magnetic resonance-emission tomography apparatus, the attenuation map generating stage is configured no that the attenuation map is generated using the magnetic resonance image data that are generated from the magnetic resonance scan data.

In a further embodiment of the combined magnetic resonance-emission tomography apparatus, the attenuation map generating stage is configured so that before the generation of the attenuation map, a transformation of the magnetic resonance image data takes place, wherein transformed magnetic resonance image data are created, wherein the generation of the attenuation map takes place using the transformed magnetic resonance image data.

In another embodiment of the combined magnetic resonance-emission tomography apparatus, the attenuation map generating stage is configured so that the transformation of the magnetic resonance image data is a change of the slice orientation of the magnetic resonance image data.

In another embodiment of the combined magnetic resonance-emission tomography apparatus, the magnetic resonance scanner and the attenuation map generating stage are configured so that the acquisition of the magnetic resonance scan data takes place with a magnetic resonance sequence which has at least one sequence parameter and the generation of the attenuation map includes post-processing of the magnetic resonance scan data using at least one post-processing parameter, with the at least one post-processing parameter being set using the at least one sequence parameter.

In another embodiment of the combined magnetic resonance-emission tomography apparatus, the magnetic resonance scanner and the attenuation map generating stage are configured so that the post-processing of the magnetic resonance scan data includes a segmentation of the magnetic resonance image data generated from the magnetic resonance scan data into a number of material classes, wherein different values of attenuation coefficients are assigned to the number of material classes.

The invention further encompasses a method for selecting at least one sequence parameter of a magnetic resonance sequence, wherein at least one input parameter, a minimum image quality and at least one post-processing parameter are pre-set. Based on the at least one pre-set input parameter, the pre-set minimum image quality and the at least one pre-set post-processing parameter, the at least one sequence parameter of the magnetic resonance sequence is determined so that magnetic resonance scan data acquired from an examination object by execution of the magnetic resonance sequence are configured so that magnetic resonance image data generated from the magnetic resonance scanner data have the pre-set minimum image quality and so that post-processing of the magnetic resonance image data for generating an attenuation map meets a post-processing quality criterion determined based on the at least one post-processing parameter. The at least one input parameter and/or the minimum image quality and/or the at least one post-processing parameter are pre-set, in particular, by a user, particularly via an input interface. The at least one sequence parameter can be selected automatically using the at least one input parameter. The procedure can also take place semi-automatically, by initially the at least one sequence parameter being generated automatically and then being adjusted by a user. The at least one input parameter can be, for example, a geometry of a sampling volume of the magnetic resonance scan data, a resolution, a number and/or an arrangement of bed positions for acquisition of the magnetic resonance scan data, etc. The use of a maximum breath-holding duration of the examination object and/or a minimum resolution has proved to be particularly advantageous as an input parameter. Naturally, a number of input parameters can be used which can be formed from any desired combination of the input parameters mentioned. Other input parameters deemed useful by those skilled in the art are also conceivable. The at least one sequence parameter is generated automatically based on a first criterion which requires a minimum image quality of the magnetic resonance image data generated from the magnetic resonance scan data. The first criterion can require the at least one minimum value for the at least one image quality parameter of the magnetic resonance image data which is described in one of the paragraphs above. The at least one sequence parameter is also determined automatically based on the post-processing quality criterion which is determined based on the at least one post-processing parameter. If a segmentation is used for post-processing the magnetic resonance image data, the post-processing quality criterion can ensure a segmentability of the magnetic resonance image data into a number of material classes. A number of material classes into the magnetic resonance image data are segmented to generate the attenuation map can be pre-set by a user or automatically. The post-processing quality criterion can then require the minimum contrast difference between a number of material classes in the magnetic resonance image data, which was described in one of the paragraphs above. If a registration is used for post-processing of the magnetic resonance scan data, the post-processing quality criterion can require a registration accuracy and/or an image quality of the registered image and/or an edge sharpness of the registered image. Based on the at least one input parameter, the at least one sequence parameter for the magnetic resonance sequence can then be selected, taking account of the minimum image quality and of the post-processing criterion. Possible sequence parameters are described above. This inventive procedure advantageously ensures that the at least one sequence parameter of the magnetic resonance sequence is configured such that the magnetic resonance scan data acquired by means of the magnetic resonance sequence are suitable, firstly, for generating diagnostic magnetic resonance image data and, secondly, for generating an attenuation map for attenuation correction of emission tomography scan data.

In an embodiment of the method for selecting at least one sequence parameter, the at least one input parameter is a maximum breath-holding duration of the examination object. A general value can be set for the maximum breath-holding duration. This general value can be, for example, 19 seconds. The maximum breath-holding duration can also be set specifically for individual examination objects. In this regard, the maximum breath-holding duration can be pre-set manually by a user via an input interface. It is also conceivable that the maximum breath-holding duration to be set automatically based on known information about the examination object. Information about the examination object can be, for example, the age of the examination object, the height of the examination object, the weight of the examination object, the sex of the examination object, etc. The at least one sequence parameter of the magnetic resonance sequence is selected taking account of the maximum breath-holding duration of the examination object particularly so that a duration of the acquisition of the magnetic resonance scan data by means of the magnetic resonance sequence does not exceed the maximum breath-holding duration. It can thus be advantageously ensured that the magnetic resonance scan duration can be encompassed within the breath-holding process of the examination object.

The advantages of the method according to the invention for selecting at least one sequence parameter of a magnetic resonance sequence and of the combined magnetic resonance-emission tomography apparatus according to the invention correspond essentially to the advantages of the method according to the invention for imaging an examination object by operation of a combined magnetic resonance-emission tomography device, which have already been described in detail. Features, advantages and alternative embodiments mentioned herein are applicable to all aspects of the invention. The functional features of the method are realized by suitable modules, in particular, hardware modules.

### BRIEF DESCRIPTION OF THE DRAWINGS

FIG. 1 schematically illustrates a combined magnetic resonance-emission tomography device according to the invention.

FIG. 2 is a flowchart of a first embodiment of the method according to the invention for imaging an examination object by operation of a combined magnetic resonance-emission tomography apparatus.

FIG. 3 is a flowchart of a second embodiment of the method according to the invention for imaging an examination object by operation of a combined magnetic resonance-emission tomography apparatus.

FIG. 4 is a flowchart of an embodiment of the method according to the invention for selecting at least one sequence parameter of a magnetic resonance sequence.

### DESCRIPTION OF THE PREFERRED EMBODIMENTS

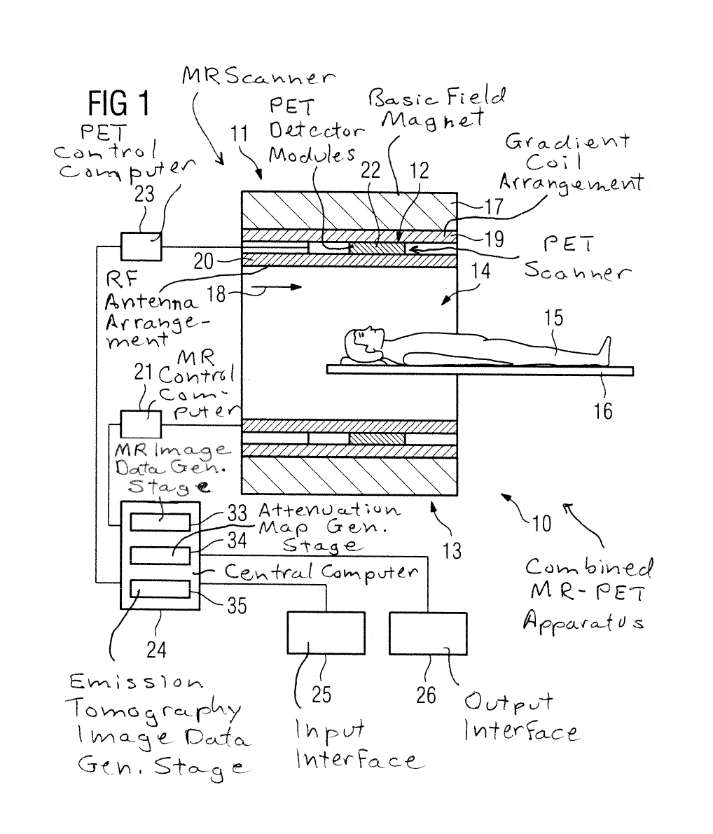

FIG. 1 shows a combined magnetic resonance-emission tomography apparatus according to the invention in a schematic representation. The magnetic resonance-emission tomography apparatus is configured, as an example, as a magnetic resonance-positron emission tomography apparatus (MR-PET apparatus) 10. The MR-PET apparatus 10 has an MR scanner 11. The MR-PET apparatus 10 also has a positron emission tomography scanner (PET scanner) 12. Alternatively, it is also conceivable for the magnetic resonance-emission tomography apparatus to be configured as a magnetic resonance-single photon emission computed tomography (MR-SPECT) apparatus. The MR-SPECT apparatus then has, rather than the PET scanner 12, a single photon emission computed tomography unit (SPECT scanner).

The magnetic resonance scanner 11 has a magnet unit 13 and a patient receiving region 14 surrounded by the magnet unit 13 for accommodating an examination object 15, in particular a patient 15, wherein the patient receiving region 14 is cylindrically surrounded in a peripheral direction by the magnet unit 13. The patient 15 can be moved by a patient support 16 of the magnetic resonance-PET device 10 into the patient receiving region 14. For this purpose, the patient support 16 is movably arranged within the patient receiving region 14.

The magnet unit 13 has a basic field magnet 17 that is configured to generate, during operation of the magnetic resonance scanner 11, a strong and constant basic magnetic field 18. The magnet unit 13 also has a gradient coil arrangement 19 for generating magnetic field gradients that are used for spatial encoding during imaging. Furthermore, the magnet unit 13 has a radio-frequency antenna arrangement 20 which, in the embodiment shown, is configured as a body coil firmly integrated into the magnetic resonance scanner 11. The body coil is operated to cause certain nuclear spins within the patient 15 to depart from the polarization produced by the basic magnetic field 18 generated by the basic field magnet 17. The radio-frequency antenna arrangement 20 is also configured to receive magnetic resonance signals.

For controlling the basic field magnet 17, the gradient coil arrangement 19 and to control the radio-frequency antenna arrangement 20, the magnetic resonance-PET device 10, in particular the magnetic resonance scanner 11, has a magnetic resonance control computer 21. The magnetic resonance control computer 21 controls the magnetic resonance scanner 11, for example, the execution of a pre-determined imaging gradient echo sequence, centrally. For this purpose, the magnetic resonance control computer 21 includes a gradient control unit (not shown in detail) and a radio-frequency antenna control unit (not shown in detail). Furthermore, the magnetic resonance control computer 21 includes an evaluation unit (not shown in detail) for evaluating magnetic resonance image data.

The magnetic resonance scanner 11 can naturally have further components that magnetic resonance scanners typically have. The general mode of operation of a magnetic resonance scanner is known to those skilled in the art, so that a more detailed description is not necessary herein.

The PET scanner 12 has a number of positron emission-tomography detector modules 22 (PET-detector modules 22) that are arranged annularly to surround the patient receiving region 14 in the peripheral direction. The PET detector modules 22 each have a number of positron emission tomography detector elements (PET detector elements) (not shown in detail), which are arranged as a PET detector array that has a scintillation detector array with scintillator crystals, for example LSO crystals. Furthermore, the PET detector modules 22 each have a photodiode array, for example, an avalanche photodiode (APD) array, which are arranged downstream of the scintillation detector array within the PET detector modules 22.

With the PET detector modules 22, photon pairs that result from the annihilation of a positron with an electron are detected. The trajectories of the two photons form an angle of 180°. In addition, the two photons each have an energy of 511 keV. The positron is emitted by a radiopharmaceutical that is administered to the patient 15 by an injection. On passing through tissue, photons arising from the annihilation can be attenuated, with the attenuation probability depending on the path length through the tissue and the corresponding attenuation coefficient of the tissue. Accordingly, when the PET signals are evaluated, a correction of these signals with respect of the attenuation through tissue or other components situated in the ray path is necessary.

In addition, the PET detector modules 22 each have a detector electronics unit which comprises an electric amplifier circuit and further electronic components (not shown in detail). For controlling the detector electronics unit and the PET detector modules 22, the magnetic resonance-PET device 10, in particular the PET scanner 12, has a PET control computer 23. The PET control unit 23 centrally controls the PET scanner 12. Furthermore, the PET control computer 23 includes an evaluation unit for evaluating PET data.

The PET scanner 12 can naturally have further components that PET scanners typically have. The general mode of operation of a PET scanner is known to those skilled in the art, no that a detailed description is not necessary herein.

The magnetic resonance-PET device 10 also has a central computer unit 24 which, for example, matches acquisition and/or evaluation of magnetic resonance scan data and PET scan data to one another. The computer 24 can be a central system control computer. Control information such as, for example, imaging parameters and reconstructed magnetic resonance images can be displayed for a user on a display monitor 25, for example on at least one monitor of the magnetic resonance-PET device 10. In addition, the magnetic resonance-PET device 10 has an input interface 26 via which information and/or parameters can be entered by a user during a scanning procedure. The computer 24 can include the magnetic resonance control computer 21 and/or the PET control computer 23.

The computer 24 further has a magnetic resonance image data generating stage 33, an attenuation map generating stage 34 and an emission tomography image data generating stage 35.

Thus the magnetic resonance-PET apparatus 10 is configured to implement the method according to the invention for imaging the examination object 15.

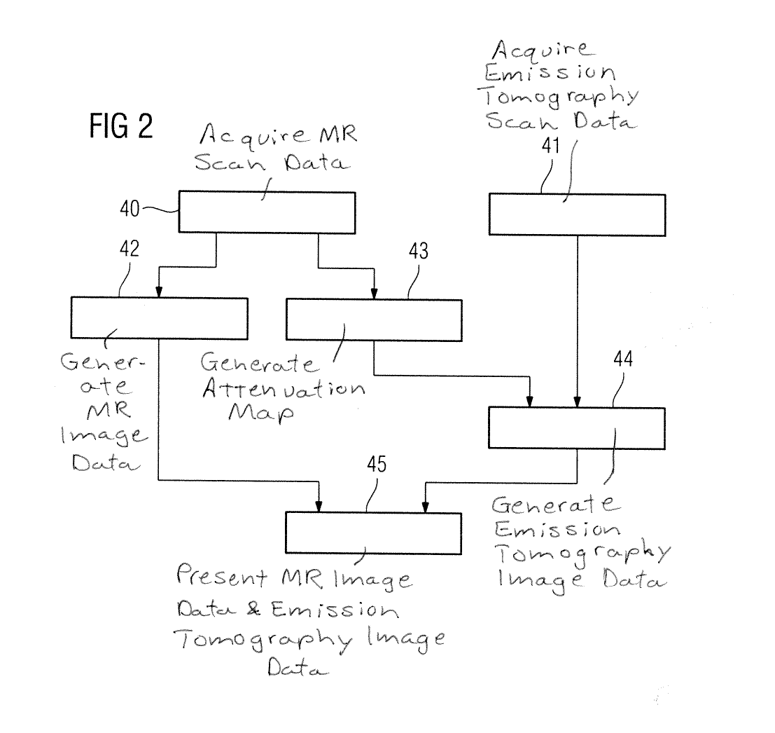

FIG. 2 is a flowchart of a first embodiment of the method according to the invention for imaging an examination object 15 by operation of a combined magnetic resonance-emission tomography apparatus 10.

In a first method step 40, acquisition of magnetic resonance scan data of the examination object 15 by operation of the magnetic resonance scanner 11 of the magnetic resonance-emission tomography apparatus 10 takes place. The magnetic resonance scan data are acquired by execution of a magnetic resonance sequence.

In a further method step 41, acquisition of emission tomography scan data of the examination object 15 take place by operation of an emission tomography scanner 12 of the magnetic resonance-emission tomography apparatus 10.

In a further method step 42, generation of magnetic resonance image data from the magnetic resonance scan data by the magnetic resonance image data generating stage 33 of the computer 24 takes place. The generation of the magnetic resonance image data can be a reconstruction of the magnetic resonance image data from the magnetic resonance scan data.

In a further method step 43, the attenuation map generating stage 34 of the computer 24 generates an attenuation map using the acquired magnetic resonance scan data that are used to generate the magnetic resonance image data to be displayed. The generation of the attenuation map advantageously takes place, as shown in FIG. 2, on the basis of the same magnetic resonance scan data that are used for the reconstruction of the magnetic resonance image data. The magnetic resonance scan data acquired by the at least one magnetic resonance sequence can thus be used, firstly, for reconstructing the magnetic resonance image data and, secondly, for generating the attenuation map. The generation of the attenuation map can also take place other than as shown in FIG. 2 using the generated magnetic resonance image data. Then the further method step 43 takes place following the further method step 42.

In a further method step 44, an emission tomography image data generating stage 35 of the computer 24 generates emission tomography image data by execution of an attenuation correction of the emission tomography scan data, wherein the attenuation correction takes place using the generated attenuation map.

In a further method step 45, presentation of the magnetic resonance image data and the emission tomography image data on the display monitor 25 takes place. The magnetic resonance image data that are shown are based on the magnetic resonance scan data that were used for generating the attenuation map.

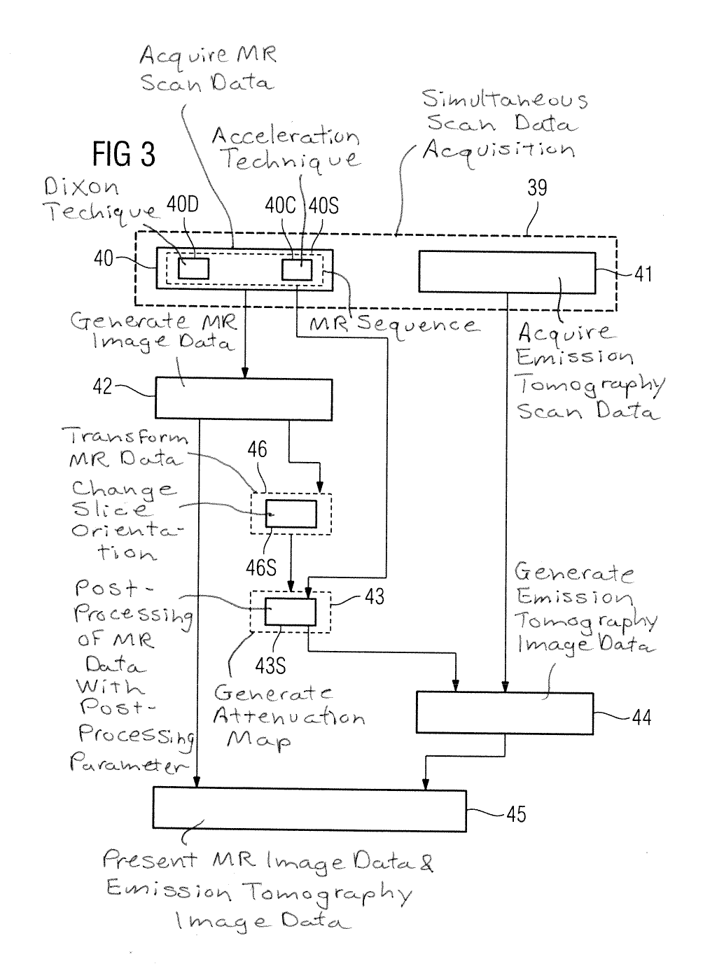

FIG. 3 is a flowchart of a second embodiment of the method according to the invention for imaging an examination object 15 by operation of the combined magnetic resonance-emission tomography apparatus 10.

The following description is essentially restricted to the differences from the exemplary embodiment in FIG. 2 wherein, with regard to method steps that remain the same, the description of the exemplary embodiment in FIG. 2 applies. Method steps that are substantially the same are identified with the same reference signs.

The second embodiment of the method according to the invention shown in FIG. 3 includes the method steps 40, 41, 42, 43, 44, 45 of the first embodiment of the method according to the invention as shown in FIG. 2. In addition, the second embodiment of the method according to the invention shown in FIG. 3 has further method steps and sub-steps. Also conceivable is an alternative method sequence to that of FIG. 3 that has only some of the additional method steps and/or sub-steps represented in FIG. 2. Naturally, an alternative method sequence to that of FIG. 3 can also have additional method steps and/or sub-steps.

In a further method step 39, a simultaneous magnetic resonance-emission tomography examination of the examination object 15 by operation of the magnetic resonance-emission tomography apparatus 10 takes place. During this simultaneous magnetic resonance-emission tomography examination, the acquisition of the magnetic resonance scan data in the further method step 40 and the acquisition of the emission tomography scan data in the further method step 41 takes place at least partially simultaneously. The magnetic resonance scan data and the emission tomography scan data are acquired from the same examination object 15.

The acquisition of the magnetic resonance scan data in the further method step 40 is carried out by execution of a magnetic resonance sequence 40S. The magnetic resonance sequence 40S stipulates a series of control commands, by which the magnetic resonance scanner 11 acquires the magnetic resonance scan data. In the present exemplary embodiment, the magnetic resonance sequence 40S uses a Dixon technique 40D with an acceleration technique 40C. Preferably, the acceleration technique 40C uses a CAIPIRINHA (Controlled Aliasing In Parallel Imaging Results In Higher Acceleration) recording method 40C. In this way, the magnetic resonance scan data can be acquired with a high acceleration factor, so that, for example, acquisition of the magnetic resonance scan data with a high spatial resolution is possible. In this way it can be ensured that the thus acquired magnetic resonance scan data are configured such that the magnetic resonance image data generated in the further method step 42 from the magnetic resonance scan data have a sufficient image quality for a diagnostic assessment when they are shown on the display monitor 25 in the further method step 45. In particular, in this way, the magnetic resonance scan data are configured such that a resolution of the magnetic resonance image data generated from the magnetic resonance scan data is higher at least in one spatial direction than a resolution of the emission tomography image data.

The magnetic resonance image data reconstructed from the magnetic resonance scan data in the further method step 42 are used in the further method step 43 by the attenuation map generating stage 34 to generate the attenuation map. For this purpose, before the generation of the attenuation map, the magnetic resonance image data are initially transformed by the computer 24 in a further method step 46. The transformation of the magnetic resonance image data can be a change of the slice orientation of the magnetic resonance image data by the computer 24 in a sub-step 46S of the further method step 46.

A possible transformation of the magnetic resonance image data for generating the attenuation map will now be explained with reference to an exemplary situation. As an example, in the further method step 40, magnetic resonance scan data are acquired in different bed positions by the magnetic resonance scanner 11. The magnetic resonance scan data therefore include a number of partial scan data sets, wherein each of the multiple partial scan data sets is acquired with a different bed position. From the multiple partial scan data sets, in the further method step 42, a number of partial image data sets are then reconstructed. The magnetic resonance image data then include the number of partial image data sets. The magnetic resonance image data are configured in an axial slice orientation. The magnetic resonance image data thus include a number of slices that are arranged perpendicularly to a longitudinal body axis of the examination object 15 in the axial direction. The axial slice orientation has proved to be particularly advantageous for a diagnostic assessment, so that the axially oriented magnetic resonance image data can be displayed in the further method step 45.

The number of slices is distributed over the different partial image data sets. There is, for example, at least a partial overlap of the recorded slices. This means that the same slices are contained in different partial image data sets. For the generation of the attenuation map in the further method step 43, the number of partial image data sets is to be brought together so that, from the multiple partial image data sets, a single attenuation map can be generated for attenuation correction of the emission tomography scan data.

However, a trivial joining together of the multiple axially oriented partial image data sets is typically not possible, due to the overlapping of the axial slices. Therefore, the multiple partial image data sets are advantageously transformed by the a slice orientation of the individual partial image data sets is changed into a sagittal slice orientation. The thus-transformed partial image data sets can be brought together particularly easily into a single transformed magnetic resonance image data set. This can possibly be transformed again into another slice orientation if this is necessary for generating the attenuation map. In any event, the transformed magnetic resonance image data set can now be used particularly advantageously in the further method step 43 to generate the attenuation map.

The generation of the attenuation map in the further method step 43 in the case shown includes a post-processing of the magnetic resonance scan data by means of the attenuation map generating stage 34 in a sub-step 43S of the further method step 43. The post-processing of the magnetic resonance scan data herein takes place using at least one post-processing parameter, with the at least one post-processing parameter being generated using at least one sequence parameter of the magnetic resonance sequence 40S. For this purpose, the at least one sequence parameter of the magnetic resonance sequence 40S is transferred by the magnetic resonance scanner 11 to the attenuation map generating stage 34.

A post-processing of the magnetic resonance scan data will now be described using an exemplary case and taking account of the at least one sequence parameter of the magnetic resonance sequence 40S. In this example, the post-processing of the magnetic resonance scan data includes a segmentation of the magnetic resonance image data into a number of material classes. Herein, different values of attenuation coefficients are associated with the number of material classes. Based on the at least one sequence parameter of the magnetic resonance sequence 40S, for example, a measure for an expected image quality of the magnetic resonance image data, for example, a mean signal-to-noise ratio to be expected, is calculated. Based on the calculated measure of the expected image quality, a threshold value for the segmentation of the magnetic resonance image data can then be adapted to the plurality of material classes. If for example, the expected signal-to-noise ratio is high, the threshold value for the segmentation can be raised. If herein, for example, the expected signal-to-noise ratio is low, the threshold value for the segmentation can be lowered. Thus, the segmentation of the magnetic resonance image data can be particularly easily matched to an image quality of the magnetic resonance image data.

Following the post-processing of the magnetic resonance scan data in sub-step 43S, the attenuation map can be generated particularly easily using the attenuation coefficients assigned to the material classes. The attenuation map can then be used in the attenuation correction of the emission tomography scan data. The emission tomography image data thus reconstructed by the attenuation correction in the further method step 44 can be displayed in the further method step 45, in particular fused with the magnetic resonance image data, on the display monitor 25.

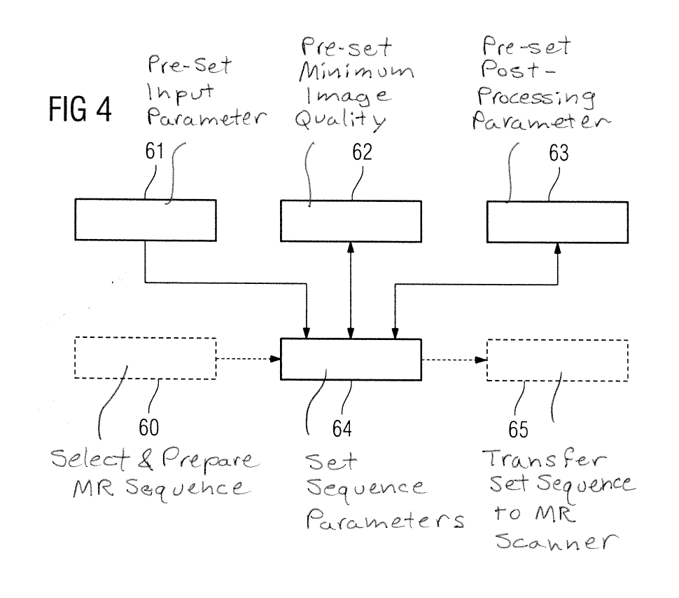

FIG. 4 is a flowchart of an embodiment of the method according to the invention for selecting at least one sequence parameter of a magnetic resonance sequence.

In a first method step 60, a selection and preparation of a magnetic resonance sequence take place. This can mean that a user stipulates, via input interface 26 of the magnetic resonance-emission tomography apparatus 10, a type of the magnetic resonance sequence and/or seeks a suitable protocol in which a particular magnetic resonance sequence is defined. Alternatively, a suitable magnetic resonance sequence can be selected automatically. The magnetic resonance sequence can include, for example, a number of sequence parameters that are to be set. Alternatively to the method described in FIG. 4, it is also conceivable for only one sequence parameter of the magnetic resonance sequence to be set. For example, the following sequence parameters are possible: a slice thickness, a slice increment, a number of slices, a positioning of the slices in the examination object 15, a resolution, a repetition time, an echo time, etc.

In a further method step 61, at least one input parameter is pre-set. More than one input parameter can be pre-set. The input parameters can be pre-set by a user via the input interface 26 of the magnetic resonance-emission tomography apparatus 10. The at least one input parameter preferably sets at least one limit condition for the sequence parameters of the magnetic resonance sequence. The at least one input parameter can be a maximum breath-holding duration of the examination object 15.

In a further method step 62, a minimum image quality is pre-set. The minimum image quality can be pre-set by a user via the input interface 26 of the magnetic resonance-emission tomography apparatus 10. The minimum image quality can herein be pre-set so that a resolution of the magnetic resonance image data generated from the magnetic resonance scan data is at least twice as high as a resolution of the emission tomography image data.

In a further method step 63, at least one post-processing parameter is pre-set. The at least one post-processing parameter can be pre-set, in particular, by a user via the input interface 26 of the magnetic resonance-emission tomography apparatus 10.

In a further method step 64, sequence parameters of the magnetic resonance sequence are set. The sequence parameters can herein be generated from scratch. Alternatively, pre-set sequence parameters can also be adapted. The setting of the sequence parameters can take place fully automatically. Alternatively, it can also take place semi-automatically in that the possibility is provided to a user via the input interface 26 of the magnetic resonance-emission tomography apparatus 10 to adapt the sequence parameters. The sequence parameters are herein determined based on the at least one pre-set input parameter, the pre-set minimum image quality and the at least one pre-set post-processing parameter. The sequence parameters are herein determined in that magnetic resonance scan data acquired from an examination object by the magnetic resonance sequence are configured such that magnetic resonance image data generated from the magnetic resonance scan data have the pre-set minimum image quality and that a post-processing of the magnetic resonance image data for generating an attenuation map meets a post-processing quality criterion determined based on the at least one post-processing parameter.

The further method step 64 includes the setting of the sequence parameters interacts with the further method step 62. In this further method step 62, it is ensured that magnetic resonance scan data acquired from an examination object 15 by means of the magnetic resonance sequence are configured such that magnetic resonance image data generated from the magnetic resonance scan data have the pre-set minimum image quality. The sequence parameters can be generated based on a first criterion which requires a minimum image quality of the magnetic resonance image data generated from the magnetic resonance scan data. The first criterion can define limit conditions within which the sequence parameters of the magnetic resonance sequence can be varied automatically or manually. Before a magnetic resonance sequence with a particular setting of sequence parameters is approved for acquiring magnetic resonance scan data, in the further method step 62, it can be checked whether the magnetic resonance scan data meet the first criterion.

Furthermore, the further method step 64 that includes the setting of the sequence parameters interacts with the further method step 63. In this further method step 63, it is ensured that magnetic resonance scan data acquired from an examination object 15 by the magnetic resonance sequence are configured such that a post-processing of the magnetic resonance image data to generate an attenuation map meets a post-processing quality criterion determined based on the at least one post-processing parameter. The sequence parameters can be generated based on the post-processing quality criterion, which ensures a quality of the post-processing of the magnetic resonance scan data. The post-processing quality criterion can define limit conditions within which the sequence parameters of the magnetic resonance sequence can be varied automatically or manually. Before a magnetic resonance sequence with a particular setting of sequence parameters is approved for acquiring magnetic resonance scan data, in the further method step 63, it can be checked whether the magnetic resonance scan data meet the post-processing quality criterion.

The magnetic resonance sequence can be transferred to the magnetic resonance scanner 11 following setting of the sequence parameters in a further method step 65. The magnetic resonance control computer 21 of the magnetic resonance scanner 11 can generate the relevant control commands for acquiring the magnetic resonance scan data from the magnetic resonance sequence. In this way, the magnetic resonance sequence can be used to acquire magnetic resonance scan data. The magnetic resonance scan data acquired by the magnetic resonance sequence can be further processed in accordance with an embodiment of the method according to the invention shown in FIG. 2 or FIG. 3 for imaging an examination object 15 by means of a combined magnetic resonance-emission tomography device 10.

The steps of the method according to the invention shown in FIG. 4 for the selection of sequence parameters of a magnetic resonance sequence are carried out by the computer. For this purpose, the computer has the required software and/or computer programs that are stored in a memory of the computer. The software and/or computer programs include program code configured to implement the method according to the invention when the computer program and/or the software in the computer are executed by a processor of the computer.

Although modifications and changes may be suggested by those skilled in the art, it is the intention of the inventors to embody within the patent warranted hereon all changes and modifications as reasonably and properly come within the scope of their contribution to the art.

We claim as our invention:

1. A method for acquiring image data from an examination object by operation of a combined magnetic resonance-emission tomography apparatus, comprising:
operating a magnetic resonance scanner in a combined magnetic resonance-emission tomography apparatus, while an examination object is situated in the apparatus, to acquire magnetic resonance scan data from the examination object;
operating an emission tomography scanner of said combined magnetic resonance-emission tomography apparatus, while the examination object is situated in the apparatus, to acquire emission tomography scan data from the examination object;
in a processor, generating magnetic resonance image data from the magnetic resonance scan data;
in said processor, generating an attenuation map using the acquired magnetic resonance scan data that are used to generate the magnetic resonance image data;
in said processor, generating emission tomography image data by applying an attenuation correction using the generated attenuation map, to the emission tomography scan data; and
at a display monitor in communication with said processor, displaying said magnetic resonance image data and said emission tomography image data.

2. A method as claimed in claim 1 comprising operating said magnetic resonance scanner and said emission tomography scanner at least partially simultaneously to acquire said magnetic resonance scan data and said emission tomography scan data.

3. A method as claimed in claim 1 comprising operating said magnetic resonance scanner to acquire said magnetic resonance scan data with a quality that is at a level to make a diagnostic assessment from the magnetic resonance image data at said display monitor.

4. A method as claimed in claim 1 comprising operating said magnetic resonance scanner and said emission tomography scanner to acquire said magnetic resonance scan data to produce a resolution of said magnetic resonance image data that is higher in at least one spatial direction than a resolution of the emission tomography image data.

5. A method as claimed in claim 1 comprising operating said magnetic resonance scanner to acquire to said magnetic resonance scan data by executing a magnetic resonance data acquisition sequence using a Dixon technique with an acceleration technique.

6. A method as claimed in claim 5 comprising operating said magnetic resonance scanner using a CAIPIRINHA acquisition method as said acceleration technique.

7. A method as claimed in claim 1 comprising, before generating said attenuation map, applying a transformation algorithm in said processor to said magnetic resonance image data thereby producing transformed magnetic resonance image data, and generating said attenuation map using the transformed magnetic resonance image data.

8. A method as claimed in claim 7 wherein said magnetic resonance image data, before applying said transformation algorithm, exhibit a slice orientation, and applying said transformation algorithm to change said slice orientation in the transformed magnetic resonance image data.

9. A method as claimed in claim 1 comprising operating said magnetic resonance scanner to acquire said magnetic resonance scan data by executing a magnetic resonance sequence comprising at least one sequence parameter, and generating said attenuation map in a post-processing procedure executed in said processor, said post-processing procedure comprising at least one post-processing parameter, and determining said at least one post-processing parameter in said processor dependent on said at least one sequence parameter.

10. A method as claimed in claim 9 comprising, in said post-processing procedure, segmenting said magnetic resonance image data generated from said magnetic resonance scan data into a plurality of material classes, and generating said attenuation map to assign a respective attenuation coefficient to each of said plurality of material classes, with the respective attenuation coefficients having different values.

11. A combined magnetic resonance-emission tomography apparatus comprising:
a magnetic resonance scanner comprising a patient receptacle;
an emission tomography scanner combined with said magnetic resonance scanner to share said patient receptacle;
a magnetic resonance control computer configured to operate the magnetic resonance scanner, while an examination object is situated in the patient receptacle, to acquire magnetic resonance scan data from the examination object;
an emission tomography control computer configured to operate the emission tomography scanner, while the examination object is situated in the patient receptacle, to acquire emission tomography scan data from the examination object;
a processor configured to generate magnetic resonance image data from the magnetic resonance scan data;
said processor being configured to generate an attenuation map using the acquired magnetic resonance scan data that are used to generate the magnetic resonance image data;
said processor being configured to generate emission tomography image data by applying an attenuation correction using the generated attenuation map, to the emission tomography scan data; and
a display monitor in communication with said processor, said processor being configured to display said magnetic resonance image data and said emission tomography image data at said display monitor.

12. A method for selecting a sequence parameter of a magnetic resonance data acquisition sequence, comprising:
in a control computer of a combined magnetic resonance-emission tomography apparatus in which magnetic resonance scan data and emission tomography scan data are to be acquired, presetting an input parameter a designation of a minimum image quality for a magnetic resonance image to be generated from said magnetic resonance scan data, and a post-processing parameter;
in said control computer, automatically determining at least one sequence parameter of a magnetic resonance data acquisition sequence that causes the magnetic resonance scan data acquired from the examination object to have said image quality and that causes emission tomography data, generated from said emission tomography scan data by applying an attenuation map thereto, to have a post-processing quality dependent on said post-processing parameter; and
from said control computer, operating said magnetic resonance scanner according to said magnetic resonance data acquisition sequence to acquire said magnetic resonance scan data, and making the acquired magnetic resonance scan data available in electronic form as a data file.

13. A method as claimed in claim 12 wherein said at least one input parameter designates a maximum breath-holding duration of said examination object.
